(19) United States
(12) Patent Application Publication
(10) Pub. No.: US 2015/0309131 A1
(43) Pub. Date: Oct. 29, 2015

(54) Knee Coil

(71) Applicant: Robert Rehner, Neunkirchen am Brand (DE)

(72) Inventor: Robert Rehner, Neunkirchen am Brand (DE)

(21) Appl. No.: 14/695,432

(22) Filed: Apr. 24, 2015

(30) Foreign Application Priority Data
Apr. 25, 2014 (DE) 102014207843.1

(51) Int. Cl. G01R 33/341; G01R 33/422; G01R 33/36; G01R 33/34; G01R 33/385

(52) U.S. Cl. CPC G01R 33/341; G01R 33/34084; G01R 33/385; G01R 33/3614; G01R 33/34069; G01R 33/3628; G01R 33/422

(57) ABSTRACT

A local coil for an imaging magnetic resonance imaging (MRI) system for knee imaging includes a shield configured to be arranged at a knee.

This application claims the benefit of DE 102014207843.1, filed on Apr. 25, 2014, which is hereby incorporated by reference in its entirety.

### FIELD

The disclosed embodiments relate to devices and methods for magnetic resonance imaging (MRI) imaging of a knee.

### BACKGROUND

Magnetic resonance imaging (MRI) devices for examining objects or patients by magnetic resonance tomography are known from, e.g., DE 103 14 215 B4.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, the disclosed embodiments may optimize MRI imaging of a knee.

### BRIEF DESCRIPTION OF THE DRAWINGS

FIG. 1A shows a local coil in accordance with one embodiment, the radio frequency (RF) antennas of which surround one knee of an examination subject, while an RF shield surrounds a further knee of the examination subject.

FIG. 1B shows a local coil in accordance with one embodiment, the RF antennas of which surround one knee of an examination subject, while an RF shield is arranged to one side of a further knee of the examination subject.

FIG. 2A shows a local coil in accordance with one embodiment, the RF antennas of which surround one knee of an examination subject, while an RF shield surrounds the RF antennas at the knee.

FIG. 2B shows a local coil in accordance with one embodiment, the RF antennas of which surround one knee of an examination subject, and in which an RF shield is disposed on a single side of the RF antennas and outside of the RF antennas in accordance with one embodiment.

FIG. 3 shows a signal-to-noise ratio (SNR) map for two phantom bottles (instead of knees) with a local coil around the left-hand bottle and without an additional shield in accordance with one embodiment, and in which the bottles are in the field of view.

FIG. 4 shows an SNR map for two phantom bottles (instead of knees) with a local coil around the left-hand bottle and without an additional shield in accordance with one embodiment, and in which the field of view only includes the left-hand bottle and the second bottle is folded-in (aliasing).

FIG. 5 shows an SNR map for two phantom bottles (instead of knees) with a local coil around the left-hand bottle in accordance with one embodiment, and in which a passive slotted RF shield is placed around the right-hand phantom bottle in accordance with one embodiment, and in which the bottles are in the field of view,

FIG. 6 shows an SNR map for two phantom bottles (instead of knees) with a local coil around the left-hand bottle in accordance with one embodiment, and in which a passive slotted RF shield is placed around the right-hand phantom bottle in accordance with one embodiment, and in which the field of view only includes the left-hand bottle and the second bottle is no longer folded-in or folded-in less (aliasing).

FIG. 7 shows an SNR map for two phantom bottles (instead of knees) with a local coil around the left-hand bottle in accordance with one embodiment, and in which the right-hand phantom bottle is removed and the field of view only includes the left-hand bottle.

FIG. 8 schematically shows an MRI system for use in connection with one embodiment.

### DETAILED DESCRIPTION

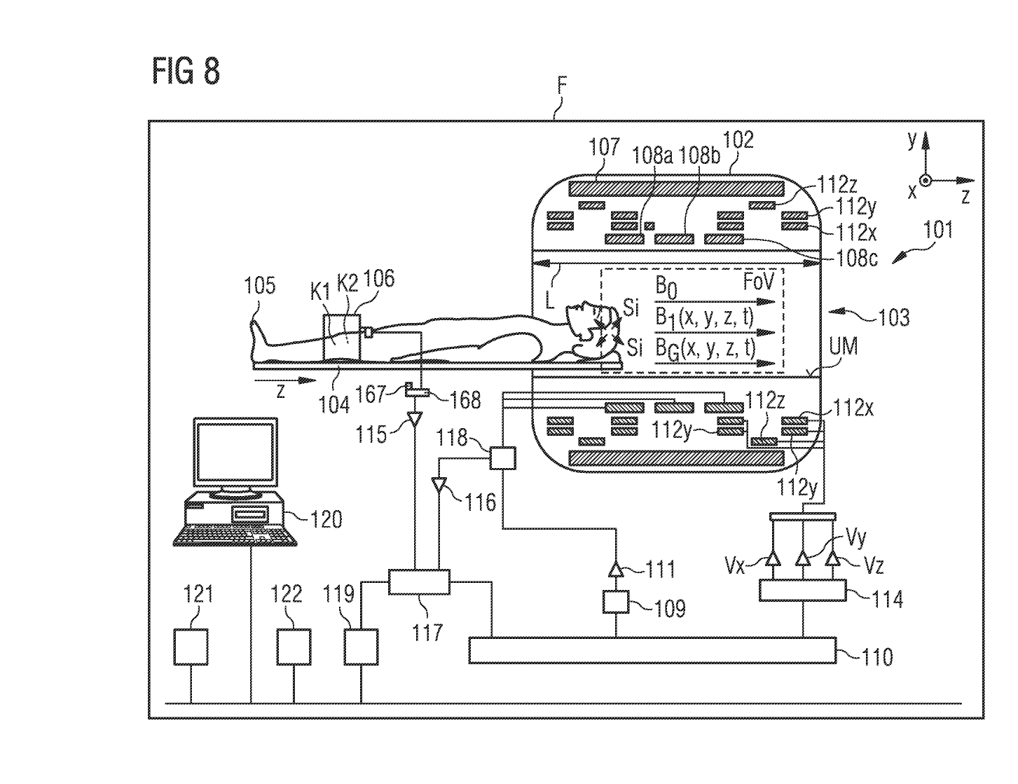

FIG. 8 shows, inter alia, an imaging magnetic resonance imaging (MRI) device 101 disposed in a shielded room or Faraday cage F with a hollow cylinder 102 with an, in this case, tubular space 103, in which a patient couch 104 with a body of, e.g., an examination object (e.g., a patient) 105 (with or without local coil arrangement 106) may be displaced in the direction of the arrow z in order to generate recordings of the patient 105 by an imaging method. In this case, a local coil arrangement 106 is arranged on the patient, via which local coil arrangement, in a local region (also referred to as field of view or FOV) of the MRI device, recordings of a portion of the body 105 in the FOV may be generated. Signals of the local coil arrangement 106 may be evaluated (e.g., converted into images, stored or displayed) by an evaluation device (168, 115, 117, 119, 120, 121, etc.) of the MRI device 101, which may be connected to the local coil arrangement 106 via, e.g., coaxial cables or by radio link (167) or other connections.

In order to use a magnetic resonance imaging device MRI device 101 to examine a body 105 (an examination object or a patient) via magnetic resonance imaging, different magnetic fields, which are precisely matched to one another in terms of their temporal and spatial characteristics, are emitted onto the body 105. A strong magnet (often a cryomagnet 107) in a measurement cabin with an opening 103, which is tunnel-shaped in this case, generates a strong static main magnetic field B₁, which has a strength of, e.g., 0.2 Tesla to 3 Tesla or more. A body 105 to be examined is, while supported by a patient couch 104, driven into a region of the main magnetic field B₁, which is approximately homogeneous in the observation region (also referred to as “field of view” or FoV). The nuclear spins of atomic nuclei of the body 105 are excited by magnetic radiofrequency excitation pulses B₁(x,y,z,t), which are emitted in via a radiofrequency antenna (and/or, optionally, a local coil arrangement), which is depicted here in a simplified manner as (e.g., multi-part=108a, 108b, 108c) body coil 108. By way of example, radiofrequency excitation pulses are generated by a pulse generation unit 109, which is controlled by a pulse sequence control unit 110. After amplification by a radiofrequency amplifier 111, the excitation pulses are conducted to the radiofrequency antenna 108. The radiofrequency system shown here is merely indicated schematically. In a magnetic resonance imaging device 101, use may also be made of more than one pulse generation unit 109, more than one radiofrequency amplifier 111 and several radiofrequency antennas 108a,b,c.

The MRI device 101 furthermore includes gradient coils 112x, 112y, 112z, by which magnetic gradient fields B_{G}(x,y,z,t) are emitted in during a measurement for selective slice excitation and for spatial encoding of the measurement signal. The gradient coils 112x, 112y, 112z are controlled by a gradient coil control unit 114 (and optionally via amplifiers Vx, Vy, Vz), which, like the pulse generation unit 109, is connected to the pulse sequence control unit 110.

Signals emitted by the excited nuclear spins (of the atomic nuclei in the examination object) are received by the body coil 108 and/or at least one local coil arrangement 106, amplified by associated radiofrequency preamplifiers 116 and processed further and digitized by a reception unit 117. The recorded measurement data are digitized and stored as complex numbers in a k-space matrix. An associated MR image may be reconstructed from the k-space matrix filled with values via a multidimensional Fourier transform.

For a coil that may be operated both in transmission mode and in reception mode, such as, e.g., the body coil 108 or the local coil 106, the correct signal transmission is regulated by an upstream transmission/reception switch 118.

An image processing unit 119 generates an image from the measurement data. The image is displayed to a user via an operating console 120 and/or stored in a storage unit 121. A central computer unit 122 controls the individual installation components.

In magnetic resonance (MR) imaging, images with a high signal-to-noise ratio (SNR) may be recorded using so-called local coil arrangements (coils, local coils). The local coil arrangements are antenna systems attached in the direct vicinity on (anterior) or under (posterior) or at or in the body 105. During an MR measurement, the excited nuclei induce a voltage in the individual antennas of the local coil, which is then amplified using a low-noise preamplifier (e.g. LNA, preamp) and transmitted to the reception electronics. In order to improve the signal-to-noise ratio, e.g., in the case of high-resolution images, use is made of so-called high-field installations (1.5 T-12 T or more). If more individual antennas may be connected to an MR reception system than receivers are available, a switching matrix (also referred to as RCCS), for example, is installed between reception antennas and receivers. The switching matrix routes the currently active reception channels (usually those that currently lie in the field of view of the magnet) to the available receivers. As a result, more coil elements may be connected than receivers are available because, in the case of a whole body cover, it is only useful to read the coils that are disposed in the FoV or in the homogeneous volume of the magnet.

By way of example, an antenna system, which may, e.g., include a single antenna element or, as an array coil, several antenna elements (e.g., coil elements), may be referred to as local coil arrangement 106. By way of example, these individual antenna elements are configured as loop antennas (loops), butterfly coils, flex coils or saddle coils. By way of example, a local coil arrangement includes coil elements, a preamplifier, further electronics (standing wave traps etc.), a housing, supports and usually a cable with plug, via which the local coil arrangement is connected to the MRI installation. A receiver 168 attached to the installation side filters and digitizes a signal received from a local coil 106, e.g., by radio link etc., and transmits the data to a digital signal processing device, which may derive an image or a spectrum from the data obtained by a measurement and makes the image available to the user, e.g., for the subsequent diagnosis by the user and/or for storing.

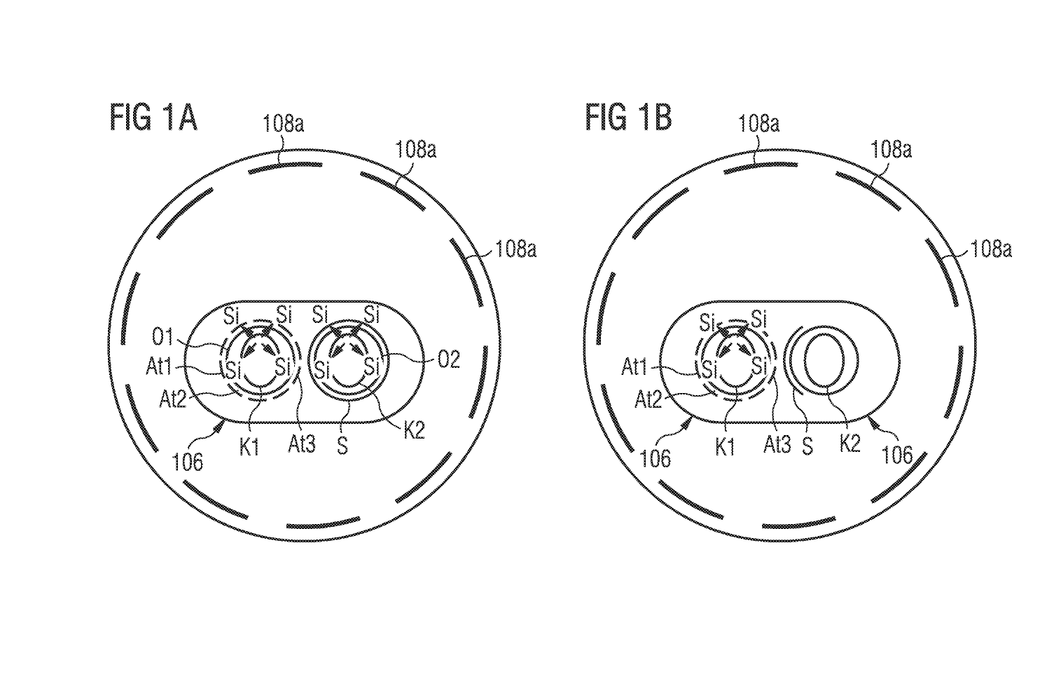

FIGS. 1-8 show details of a number of embodiments.

In MR knee imaging, the knee K1 to be examined of an examination subject or patient 104 is placed into a local coil 106 for improving the image quality. The second knee K2 is placed next to it. In order to save measuring time, e.g., the field of view (FoV) is selected to be as small as possible (and, to the extent that this is possible, only the knee K1 to be examined is acquired). Although the local coil 106 is significantly more sensitive to signals Si from within the local coil than to signals Si from outside the local coil, the antenna elements At3, which (e.g., in FIG. 1) are disposed between the two knees K1, K2, also acquire the neighboring knee. If the phase encoder in the sequence applied by the MRI 101 is selected to be “left-right”, folding-in (aliasing artifacts) may emerge in the image from the neighboring knee K2 due to undersampling.

This situation is addressed via technical measures achieving that only the knee to be examined is excited by the radiofrequency signal. This may be brought about in the following way:

1. A knee coil is equipped with a local transmission function (TX/RX coil).

2. In addition to the reception antennas, a knee coil also includes an antenna structure, e.g., in the form of a birdcage 108a,b,c, which resonates freely in the case of transmission and concentrates the transmission field of the body coil in the knee K1. If protons largely only in the knee K1 to be examined are excited in the process, it is also only these protons that supply signals Si in the reception case. As a result, the folding-in artifacts are suppressed.

According to some embodiments, excitement of only the knee to be examined may be achieved by applying an RF shield S, which may have a high shielding effect in relation to signals Si and/or Bi(x,y,z,t) in the frequency range of the MR signal Bi(x,y,z,t), but may be transmissive to frequencies in the frequency range of the gradient currents B_{G}(x,y,z,t). By way of example, this may be achieved by a slotting of the shield S. This shield may either be purely passive or else be operated in an actively switchable manner (in accordance with US Patent Publication No. 2012/0187950 A1, the entire disclosure of which is incorporated into this application by reference). The image region is excited by transmission by the body coil 108a,b,c. With respect to placement of the shield S, the two following examples may be used.

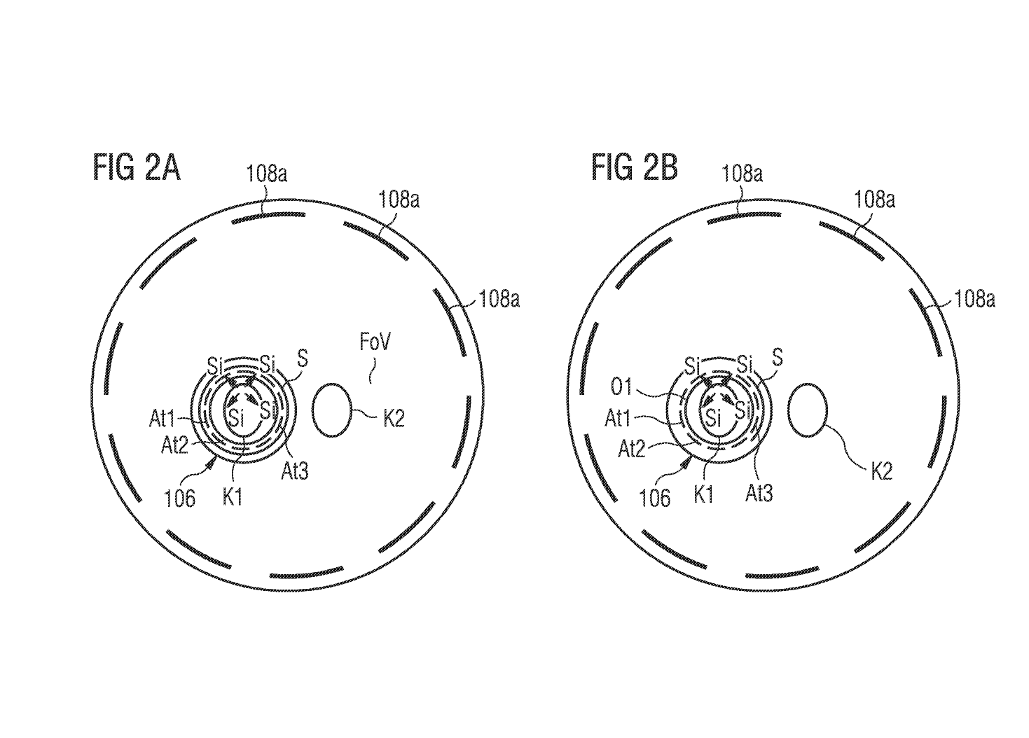

1. The shield S is placed around the neighboring knee K2 (as in FIGS. 1A, 1B, and 2A) and the knee coil 106 is mechanically equipped with two openings O1, O2 (for in each case one knee K1, K2). The reception antenna array (made of reception elements in the form of antenna elements At1, At2, At3 etc.) is attached in the housing around one of the two openings O1, O2. The shield S is applied around the other opening (in accordance with FIGS. 1 and 2) or laterally (partly circumferentially, in accordance with FIGS. 1B, 2B) therefrom. In order to examine the other knee K2 after the knee K1, the coil 106 may, e.g., be rotated by 180°.

The following three examples of the shield S may be used.

A: Passive Shield S:

A simple, passive, slotted shield S is either placed around the opening 02 of the neighboring knee K2 (in respect of the currently examined knee K1) (in accordance with FIGS. 1A, 2A) or placed only partly between the two openings O1, O2 (on the neighboring knee in accordance with FIG. 1B; on the examined knee with the RF antennas in accordance with FIG. 2B).

This shield S shields the neighboring knee K2 in, e.g., both the transmission and reception case. In the case of the partial (i.e., only lateral) shield (in accordance with FIGS. 1B and 2B), the neighboring knee K2 is excited, but emissions of signals Si from the neighboring knee K2 are shielded from the reception antennas At1-3 in the local coil 106 in the reception case (also referred to as “RX”). As a result, aliasing is avoided.

B: Active Shield S:

The active shield S may be closed (less transmissive) for RF radiation/RF signals (to radio frequencies or only to, e.g., RF excitation pulses and/or RF signals emitted by the knee) in the transmission case (which is also referred to as TX case) and open (i.e., more transmissive and/or, e.g., non-conductively interrupted by, e.g., PIN diodes) in the reception case (RX case).

By way of example, an active slotted shield S is placed around the opening 02 of the neighboring knee K2 (in accordance with FIG. 2A). It is closed via actuation currents (e.g., at one or more PIN diodes in one or more local coil antennas, e.g., in accordance with US Patent Publication No. 2012/0187950A1) in the transmission case (“TX” case) (and prevents the excitation of the protons in the neighboring knee K2 by the body coil 108a,b,c) and it is opened in the reception case (=“RX” case) (as a result, a reduction in the sensitivity of the adjacent reception elements At1, At2, At3 of the actual receiving local coil is prevented). This may also prevent aliasing.

C: Active Shield S:

An active shield S is, e.g., closed in the RX case and open in the TX case.

By way of example, an active slotted shield S is either placed around the opening O2 of the neighboring knee K2 (in accordance with FIG. 1A) or placed only partly between the two openings O1, O2 (in accordance with FIG. 1B or 2B). It is opened in the transmission case TX and both the knee K1 to be examined and the neighboring knee K2 are excited. In the reception case RX, it is closed (to radio frequencies or only to RF excitation pulses B₁(x,y,z,t) and/or RF signals Si emitted by the knee) and prevents the reception antennas At1, At2, At3 in the local coil 106 from receiving signal portions from the neighboring knee K2. Aliasing is thus prevented.

A switchable shield S around the reception elements At1, At2, At3 of the knee K1 to be examined:

An active slotted shield S is placed around the reception elements At1, At2, At3 of the knee K1 to be examined (in accordance with FIG. 2A) or it is only partly placed (i.e., placed laterally) between the two knees K1, K2 (in accordance with FIG. 1B or 2B). In the transmission case, it is set to be transparent. As a result, the knee K1 to be examined may be excited in a regular manner. The neighboring knee K2 is likewise excited. In the reception case, the switchable shield S is closed and prevents the reception antennas At1, At2, At3 in the local coil 106 from receiving signal portions Si from the neighboring knee K2. Aliasing is thus prevented.

The case 1,A has been tested in a machine.

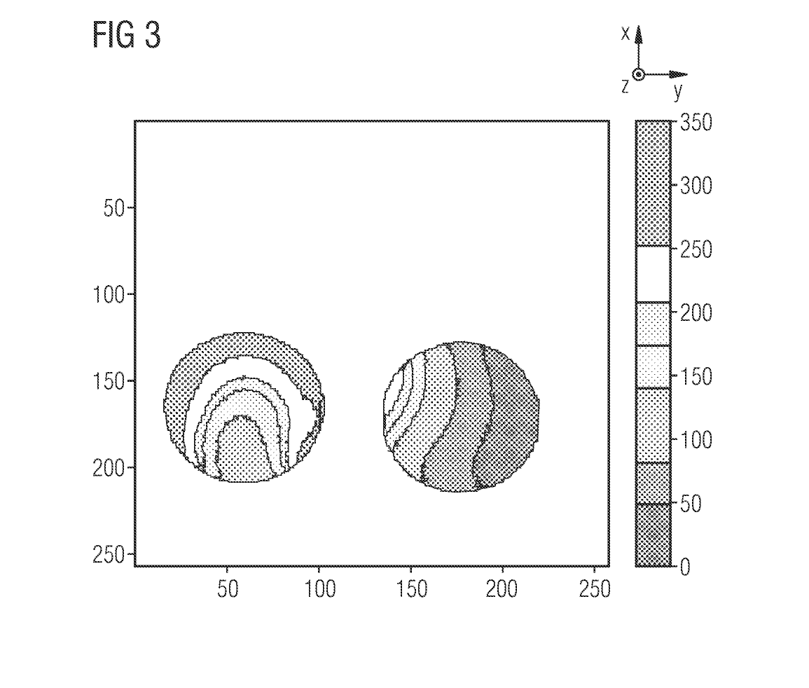

FIG. 3 shows the SNR map for two phantom bottles. A local coil 106 was placed around the left-hand bottle. No shield S was used. What may be identified is that the reception elements At1, At2, At3 of the local coil 106 also receive a significant signal Si from the right-hand bottle.

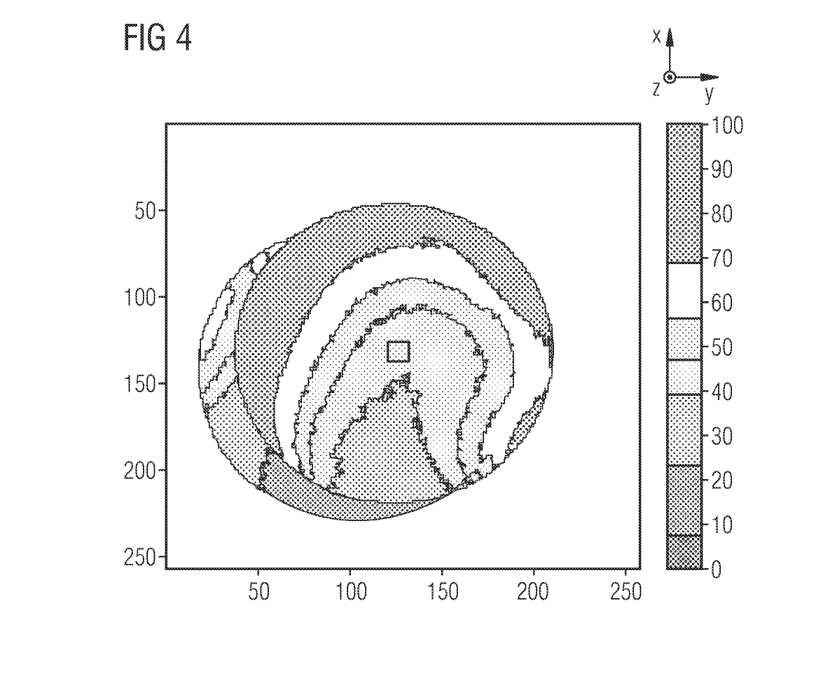

FIG. 4 shows an SNR map for two phantom bottles with a local coil 106 around the left-hand bottle. No additional shield is provided here. The field of view only encompasses the left-hand bottle. Here, the second bottle folds in (aliasing).

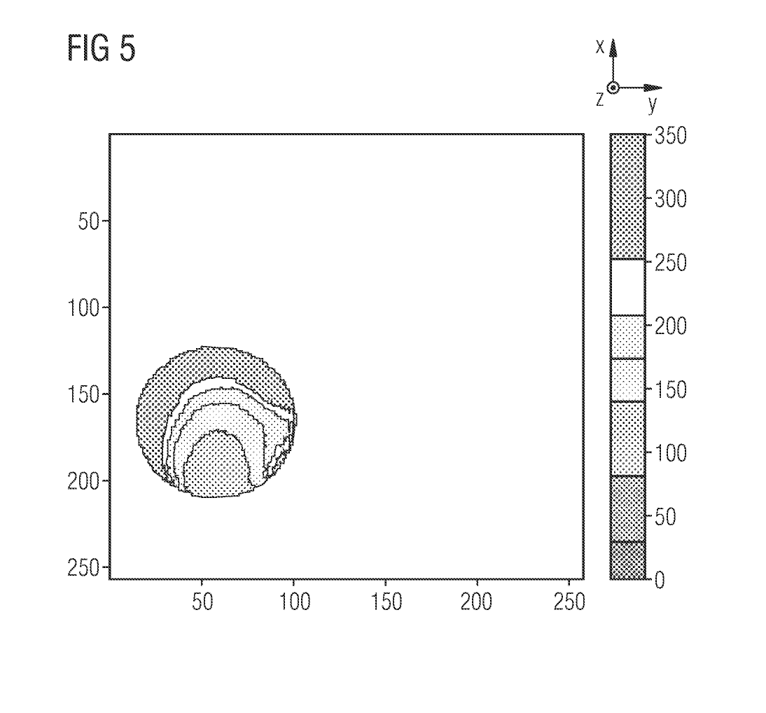

In FIG. 5, a slotted shield was placed around the right-hand bottle. The bottle is not excited and, in the reception case too, the signal Si from the right-hand bottle is shielded from the reception elements At1, At2, At3 of the right-hand bottle.

The right-hand bottle may no longer be identified on the right-hand side of the image. Accordingly, no folding-in is identifiable anymore in the case of a reduced field of view in FIG. 5 either.

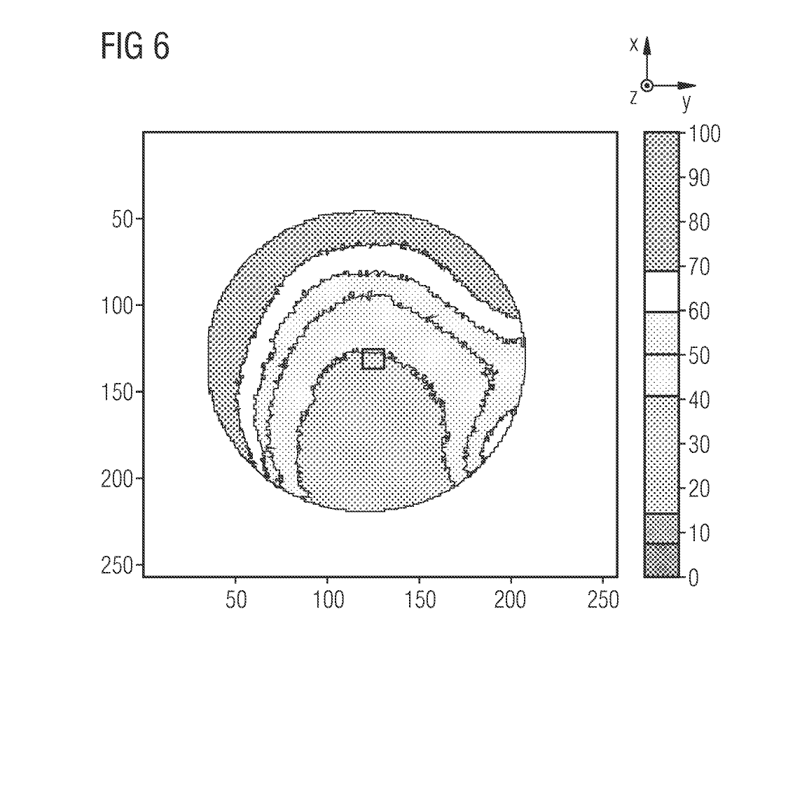

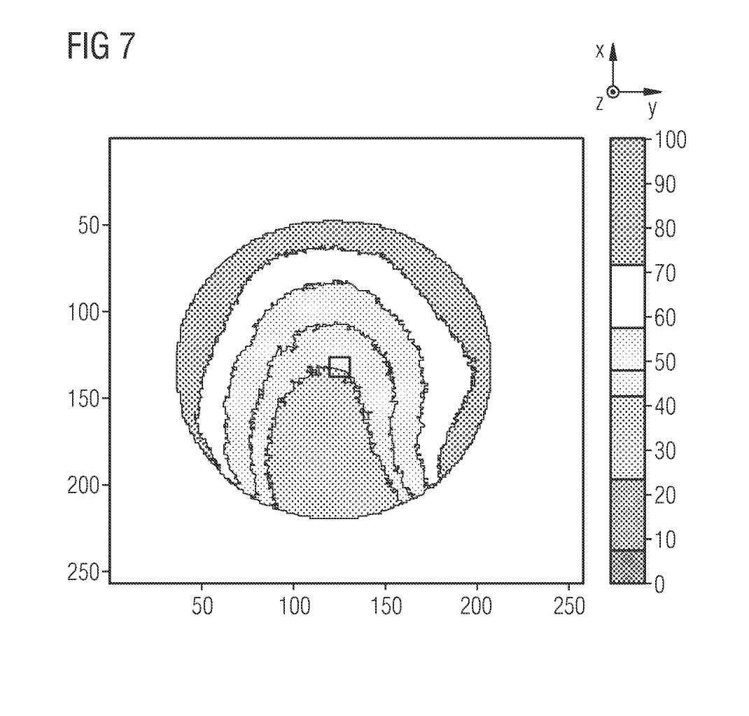

Conversely, FIG. 7 shows the SNR map in the case of a small field of view if only the left-hand bottle with a local coil is positioned in the scanner (the right-hand bottle is not present). The SNR maps in FIG. 6 and FIG. 7 are virtually identical. However, it may be identified that the SNR is slightly degraded in the right-hand region of the phantom due to the application of the shield S. This effect may be further reduced by the use of a switchable shield S.

A cost-effective alternative to TX/RX coils for avoiding aliasing effects in knee imaging is provided. Embodiments are implementable in a purely passive manner. In the case of an active embodiment, only a few PIN diodes and a switchable DC current supply may be used for the switchable shield (the switchable DC current supply is used in a local coil and for detuning the antenna elements).

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

1. A local coil for an imaging magnetic resonance imaging system for knee imaging, the local coil comprising:
a shield configured to be disposed at a knee.

2. The local coil of claim 1, wherein the shield is configured to be arranged about a longitudinal axis of a leg comprising the knee.

3. The local coil of claim 1, wherein the shield is configured to be arranged around the knee or laterally with respect to the knee, and wherein the local coil further comprises reception elements configured to be disposed at the knee.

4. The local coil of claim 1, wherein the knee is a first knee of a patient not to be imaged, wherein the shield is configured to be arranged laterally on a side of the first knee facing a second knee of the patient to be imaged, and wherein the local coil further comprises antennas configured to surround the first knee.

5. The local coil of claim 1, wherein the shield is configured to be arranged around the knee or laterally with respect to the knee, with no reception elements of the local coil being disposed at the knee.

6. The local coil of claim 1, wherein the knee is a first knee of a patient not to be imaged, and wherein the shield is configured to be arranged laterally on a side of the first knee facing a second knee of the patient to be imaged, the second knee being surrounded by antennas of the local coil.

7. The local coil of claim 1, wherein the shield is a passive shield.

8. The local coil of claim 1, wherein the shield is an active shield.

9. The local coil of claim 1, wherein the shield is closed to radio frequency (RF) radiation in a shielding manner during a reception phase of a magnetic resonance imaging system, and open to RF radiation in a transmissive manner during a transmission phase of a magnetic resonance imaging system.

10. The local coil of claim 1, wherein the shield is a slotted shield.

11. The local coil of claim 1, wherein the shield is conductive, closed, or both conductive and closed to radio frequency signals.

12. The local coil of claim 1, wherein the shield is conductive, closed, or both conductive and closed to radio frequencies via control currents when a body coil, the local, or both the body coil and the local coil are receiving, and wherein the shield is non-conductive, open, or both non-conductive and open when the local coil is transmitting.

13. The local coil of claim 1, wherein the shield is conductive, closed, or both conductive and closed to radio frequencies via control currents when a body coil, the local, or both the body coil and the local coil are receiving and transmitting.

14. The local coil of claim 1, wherein the shield is closed to radio frequency (RF) excitation pulses, RF signals, or both RF excitation pulses and RF signals emitted by the knee and configured to prevent reception antennas in the local coil from receiving signal portions from a neighboring knee.

15. The local coil of claim 1, further comprising reception elements around which the shield is arranged.

16. The local coil of claim 1, wherein the knee is a first knee to be examined, and wherein the local coil further comprises:
a further shield to be arranged on a second knee, with no reception elements of the local coil being disposed at the second knee; and
reception elements configured to be disposed at the first knee.

17. The local coil of claim 1, wherein the knee is a first knee to be examined, and wherein the local coil further comprises:
a further shield configured to be arranged on a second knee than the first knee, with no reception elements of the local coil being disposed at the second knee; and
reception elements configured to be disposed at the first knee, wherein the shield is configured to be arranged laterally from the second knee.

18. The local coil of claim 1, wherein the shield is configured to be arranged around the knee, and wherein the local coil further comprises reception elements disposed at the knee, wherein the shield is configured to be only arranged around the knee, with the knee being the sole knee at which the reception elements are disposed.

19. The local coil of claim 1, wherein the shield is configured to be arranged laterally from the knee, and wherein the local coil further comprises reception elements disposed at the knee, wherein the shield is only arranged laterally from the knee, with the knee being the sole knee at which the reception elements are disposed.

20. A method for magnetic resonance imaging of a first knee using a local coil, the local coil comprising a shield, the method comprising:
disposing the shield around the first knee or a second knee, or laterally from the first knee or the second knee; and
conducting the magnetic resonance imaging of the first knee.

21. The method of claim 20, wherein disposing the shield comprises disposing the shield around the first knee or laterally from the first knee, and wherein the method further comprises disposing reception elements of the local coil around the first knee.

22. The method of claim 20, wherein disposing the shield comprises disposing the shield around the second knee or laterally from the second knee at which no reception elements of the local coil are disposed.

23. The local coil of claim 1, wherein the shield is conductive, closed, or both conductive and closed to radio frequency (RF) excitation pulses, RF signals, or both RF excitation pulses and RF signals, emitted by the knee.

24. The local coil of claim 1, wherein the shield is conductive, closed, or both conductive and closed to radio frequency signals via control currents when a body coil, the local coil, or both the body coil and the local coil are transmitting, and wherein the shield is non-conductive, open, or both non-conductive and open when the local coil is receiving.
